(19) United States
(12) Patent Application Publication
(10) Pub. No.: US 2020/0182912 A1
(43) Pub. Date: Jun. 11, 2020

(54) ELECTRIC CURRENT SENSOR

(71) Applicant: Hitachi Metals, Ltd., Tokyo (JP)

(72) Inventors: Naoki FUTAKUCHI, Tokyo (JP); Ken OKUYAMA, Tokyo (JP); Akitoshi FUJIMORI, Tokyo (JP)

(21) Appl. No.: 16/702,202

(22) Filed: Dec. 3, 2019

(30) Foreign Application Priority Data
Dec. 10, 2018 (JP) 2018-230944

(51) Int. Cl. G01R 15/14; G01R 19/00

(52) U.S. Cl. CPC G01R 15/148; G01R 19/0092

(57) ABSTRACT

An electric current sensor includes first, second, and third current sensor modules, each including at least one bus bar formed in a rectangular shape extending in a width direction in cross section, to carry an electric current along a length direction perpendicular to the width direction, one pair of shield plates made of a magnetic material and disposed in a height direction perpendicular to the width direction and the length direction in such a manner as to sandwich the at least one bus bar therebetween, and at least one magnetic detection element disposed between the at least one bus bar and one of the one pair of shield plates, to detect a strength of a magnetic field in the width direction. The first, the second, and the third current sensor modules are arranged by superposition on top of each other in the height direction.

### CROSS-REFERENCE TO RELATED APPLICATIONS

The present invention is based on Japanese Patent Application No. 2018-230944 filed on Dec. 10, 2018, the entire contents of which are incorporated herein by reference.

### BACKGROUND OF THE INVENTION

### 1. Field of the Invention

The present invention relates to an electric current sensor.

### 2. Description of the Related Art

Conventionally, there is known an electric current sensor that includes a magnetic detection element to detect a strength of a magnetic field generated by an electric current to be measured (see, e.g., JP-A-2015-194472). By detecting the strength of the magnetic field with the magnetic detection element, the electric current can be obtained by computation based on the strength of the magnetic field.

JP-A-2015-194472 discloses a coreless electric current sensor with one pair of shield plates arranged therein in such a manner as to sandwich therebetween a bus bar, in which the electric current to be measured is to be passed, and the magnetic detection element. In the electric current sensor disclosed in JP-A-2015-194472, the magnetic detection element to detect a magnetic flux density in a plate width direction of the bus bar is used, so that the influence of an external magnetic flux is suppressed by installing the magnetic detection element in a non-permeable region that is impervious to the external magnetic flux in the plate width direction of the bus bar.

[Patent Document 1] JP-A-2015-194472

### SUMMARY OF THE INVENTION

Now, with the progress of automobile electrification, the number of electric current phases to be detected by the electric current sensor is increasing. For example, when one automobile is mounted with two three-phase AC motors (or generators having the same structure), the number of phases to be detected by the electric current sensor is six. In addition, the one automobile may also be mounted with an electric current sensor to detect another electric current, such as a single-phase electric current sensor to detect a battery side DC electric current.

Since, in this manner, the electric current sensor designed to be compatible with a large number of phases (at least seven phases) occupies a large region, the electric current sensor reduced in size is desired. However, it is not easy to reduce the size of the coreless electric current sensor because the coreless electric current sensor is easily affected by an interference between the phases, and in order to suppress this interference, the phases are required to be arranged at some distance from each other.

Accordingly, it is an object of the present invention to provide an electric current sensor that is designed to be compatible with at least seven phases, but small in size and coreless.

The present invention created to achieve the above object is an electric current sensor, comprising: first, second, and third electric current sensor modules, each including at least one bus bar formed in a rectangular shape extending in a width direction in cross section, to carry an electric current along a length direction perpendicular to the width direction, one pair of shield plates made of a magnetic material and disposed in a height direction perpendicular to the width direction and the length direction in such a manner as to sandwich the at least one bus bar therebetween, and at least one magnetic detection element disposed between the at least one bus bar and one of the one pair of shield plates, to detect a strength of a magnetic field in the width direction, wherein the first, the second, and the third electric current sensor modules are arranged by superposition on top of each other in the height direction.

Points of the Invention

According to the present invention, it is possible to provide the electric current sensor that is designed to be compatible with at least seven phases, but small in size and coreless.

### BRIEF DESCRIPTION OF THE DRAWINGS

FIG. 1 is a cross-sectional view showing an electric current sensor 1 according to a first embodiment of the present invention;

FIG. 2 is a diagram showing a computation result when a disturbance generating external magnetic field was applied in the electric current sensor 1 according to the first embodiment of the present invention;

FIG. 3 is a diagram showing a computation result when a DC electric current was applied to a bus bar 31 of an electric current sensor module 30 in the electric current sensor 1 according to the first embodiment of the present invention;

FIG. 4 is a diagram showing a computation result when a three-phase AC electric current was applied to a bus bar 21 of an electric current sensor module 20 in the electric current sensor 1 according to the first embodiment of the present invention;

FIG. 5 is a diagram showing a computation result when a three-phase AC electric current was applied to a bus bar 11 of an electric current sensor module 10 in the electric current sensor 1 according to the first embodiment of the present invention;

FIG. 6 is a cross-sectional view showing an electric current sensor 102 according to a second embodiment of the present invention;

FIG. 7 is a cross-sectional view showing an electric current sensor 103 according to a third embodiment of the present invention; and

FIG. 8 is a cross-sectional view showing an electric current sensor 104 according to a fourth embodiment of the present invention.

### DETAILED DESCRIPTION OF THE PREFERRED EMBODIMENTS

### First Embodiment

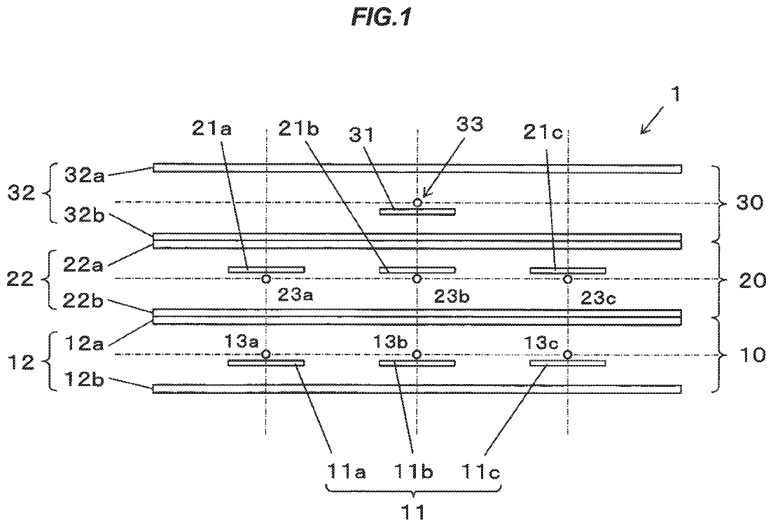

FIG. 1 is a cross-sectional view showing an electric current sensor 1 according to a first embodiment of the present invention.

As shown in FIG. 1, the electric current sensor 1 according to the embodiment of the present invention is configured to include a first electric current sensor module 10, a second electric current sensor module 20, and a third electric current sensor module 30. The first electric current sensor module 10 is configured to include a first bus bar 11, which is formed in a rectangular shape extending in a width direction in cross section, to carry an electric current along a length direction perpendicular to the width direction, one pair of first shield plates 12, which are made of a magnetic material and disposed in a height direction perpendicular to the width direction and the length direction in such a manner as to sandwich the first bus bar 11 therebetween, and a first magnetic detection element 13, which is arranged between the first bus bar 11 and one of the one pair of first shield plates 12, to detect a strength of a magnetic field in the width direction. Similarly, the second electric current sensor module 20 is configured to include a second bus bar 21, one pair of second shield plates 22, and a second magnetic detection element 23, while the third electric current sensor module 30 is configured to include a third bus bar 31, one pair of third shield plates 32, and a third magnetic detection element 33. The first electric current sensor module 10, the second electric current sensor module 20, and the third electric current sensor module 30 are arranged by superposition on top of each other in the height direction. Here, the width direction refers to the horizontal direction in FIG. 1, the height direction refers to the vertical direction in FIG. 1, and the length direction refers to the direction perpendicular to the page of FIG. 1.

(First Electric Current Sensor Module 10)

The first electric current sensor module 10 is provided between a power module designed to convert a DC electric current to an AC electric current and a three-phase AC electric current motor (or a generator having the same structure). The first electric current sensor module 10 has three bus bars, which are designed to carry three phase AC electric currents, respectively. In other words, the first bus bar 11 is composed of a first U phase bus bar 11a, which is designed to carry a U phase electric current, a first V phase bus bar 11b, which is designed to carry a V phase electric current, and a first W phase bus bar 11c, which is designed to carry a W phase electric current. On the other hand, the first magnetic detection element 13 is composed of a first U phase detection element 13a, which is arranged for the first U phase bus bar 11a, a first V phase detection element 13b, which is arranged for the first V phase bus bar 11b, and a first W phase detection element 13c, which is arranged for the first W phase bus bar 11c.

The first bus bar 11 is made of, e.g., a copper plate. The first U phase bus bar 11a, the first V phase bus bar 11b, and the first W phase bus bar 11c are being configured in such a manner as to carry the three phase AC electric currents, respectively, in the length direction. Ideally, the sum of the electric currents becomes zero at each time point. One end of the first bus bar 11 is connected to a power module, while the other end of the first bus bar 11 is connected to a three-phase AC motor (or a generator) or a connector for connecting to it. Note that the first U phase bus bar 11a, the first V phase bus bar 11b, and the first W phase bus bar 11c are preferably being arranged at equally spaced intervals in the width direction.

The first shield plates 12 are composed of a first upper shield plate 12a and a first lower shield plate 12b arranged parallel to each other. The first shield plates 12 are made of a magnetic body such as an electromagnetic steel plate, a permalloy, or the like.

The first magnetic detection element 13 is arranged between the first upper shield plate 12a and the first bus bar 11. A sensing position of the first magnetic detection element 13 is arranged in a middle (halfway) in the height direction between the first upper shield plate 12a and the first lower shield plate 12b. Accordingly, the first bus bar 11 is arranged in a location closer to the first lower shield plate 12b than the middle between the first upper shield plate 12a and the first lower shield plate 12b. Further, a sensing direction of the first magnetic detection element 13 is configured in the width direction parallel to the first shield plates 12.

The first U phase detection element 13a, the first V phase detection element 13b, and the first W phase detection element 13c of the first magnetic detection element 13 are arranged to an upper side (to a first upper shield plate 12a side) in a middle in the width direction of the first U phase bus bar 11a, the first V phase bus bar 11b, and the first W phase bus bar 11c, respectively.

(Second Electric Current Sensor Module 20)

The second electric current sensor module 20 is configured in the same manner as the first electric current sensor module 10. That is, the second electric current sensor module 20 is configured to include a second bus bar 21, which is composed of a second U phase bus bar 21a, which is designed to carry a U phase electric current, a second V phase bus bar 21b, which is designed to carry a V phase electric current, and a second W phase bus bar 21c, which is designed to carry a W phase electric current. Further, the second electric current sensor module 20 is configured to include a second magnetic detection element 23, which is composed of a second U phase detection element 23a, which is arranged for the second U phase bus bar 21a, a second V phase detection element 23b, which is arranged for the second V phase bus bar 21b, and a second W phase detection element 23c, which is arranged for the second W phase bus bar 21c. The second U phase bus bar 21a, the second V phase bus bar 21b, and the second W phase bus bar 21c are preferably being arranged at equally spaced intervals in the width direction.

The second electric current sensor module 20 is configured to include the second shield plates 22, which are composed of a second upper shield plate 22a and a second lower shield plate 22b arranged parallel to each other. The second shield plates 22 are the same in size at least in the width direction as the first shield plates 12, and are preferably the same in size in the length direction as well as the first shield plates 12. In other words, the second shield plates 22 are preferably the same in shape as the first shield plates 12.

The second magnetic detection element 23 is arranged between the second lower shield plate 22b and the second bus bar 21. A sensing position of the second magnetic detection element 23 is arranged in a middle (halfway) in the height direction between the second upper shield plate 22a and the second lower shield plate 22b. Accordingly, the second bus bar 21 is arranged in a location closer to the second upper shield plate 22a than the middle between the second upper shield plate 22a and the second lower shield plate 22b. Further, a sensing direction of the second magnetic detection element 23 is configured in the width direction parallel to the second shield plates 22.

The second electric current sensor module 20 is arranged by superposition on top of the first electric current sensor module 10. In other words, the second lower shield plate 22b is arranged in such a manner as to be superposed on top of the first upper shield plate 12a. Further, the second magnetic detection element 23 is arranged in the same location in the width direction as the first magnetic detection element 13. In other words, the second U phase detection element 23a, the second V phase detection element 23b, and the second W phase detection element 23c of the second magnetic detection element 23 are arranged in the same locations in the width direction as the first U phase detection element 13a, the first V phase detection element 13b, and the first W phase detection element 13c, respectively, of the first magnetic detection element 13.

(Third Electric Current Sensor Module 30)

The third electric current sensor module 30 is provided between the battery and the power module designed to convert a DC electric current to an AC electric current. The third electric current sensor module 30 is configured to include one third bus bar 31 (herein also referred to as P phase bus bar 31), which is designed to carry a DC electric current, and a third magnetic detection element 33 (herein also referred to as third P phase detection element 33), which is arranged for the third bus bar 31.

The third electric current sensor module 30 is configured to include the third shield plates 32, which are composed of a third upper shield plate 32a and a third lower shield 32b arranged parallel to each other. The third shield plates 32 are the same in size at least in the width direction as the first shield plates 12 and the second shield plates 22, and are preferably the same in size in the length direction as well as the first shield plates 12 and the second shield plates 22. In other words, the third shield plates 32 are preferably the same in shape as the first shield plates 12 and the second shield plates 22.

The third magnetic detection element 33 is arranged between the third upper shield plate 32a and the third bus bar 31. A sensing position of the third magnetic detection element 33 is arranged in a middle (halfway) in the height direction between the third upper shield plate 32a and the third lower shield plate 32b. Accordingly, the third bus bar 31 is arranged in a location closer to the third lower shield plate 32b than the middle between the third upper shield plate 32a and the third lower shield plate 32b. Further, a sensing direction of the third magnetic detection element 33 is configured in the width direction parallel to the third shield plates 32.

The third electric current sensor module 30 is arranged by superposition on top of the second electric current sensor module 20. In other words, the third lower shield plate 32b is arranged in such a manner as to be superposed on top of the second upper shield plate 22a. The third magnetic detection element 33 is arranged in the same location in the width direction as the first V phase detection element 13b and the second V phase detection element 23b.

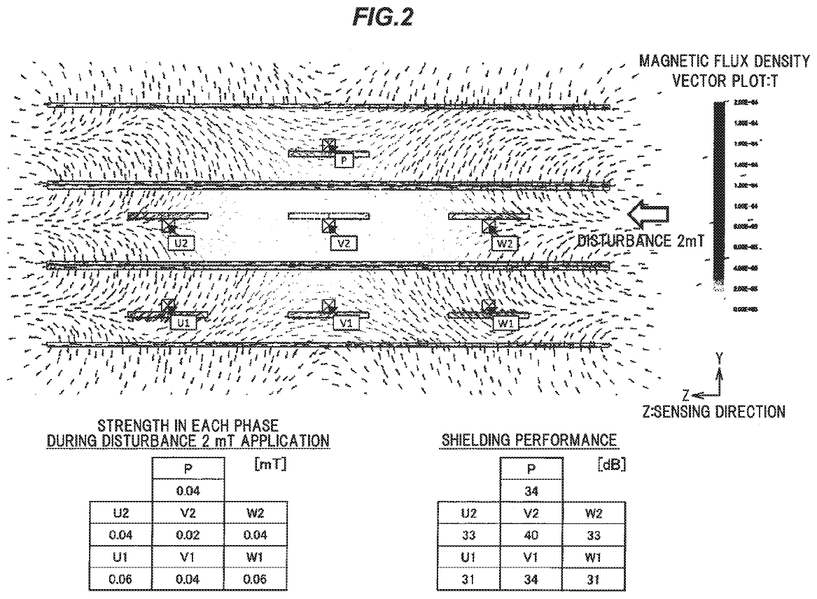

FIG. 2 is a diagram (a magnetic flux density vector diagram) showing a computation result when a disturbance generating external magnetic field was applied in the electric current sensor 1 according to the first embodiment of the present invention. A disturbance generating static magnetic field of 2 mT was applied in the width direction of the electric current sensor 1, and the shield properties were evaluated by analysis. As a result, the shielding performance was 31 dB or higher for all seven phases, and so it was confirmed that the sufficient shielding performance was obtained. Note that the shielding performance 31 dB refers to the performance that reduces the disturbance generating external magnetic field 2 mT by 1/35 times.

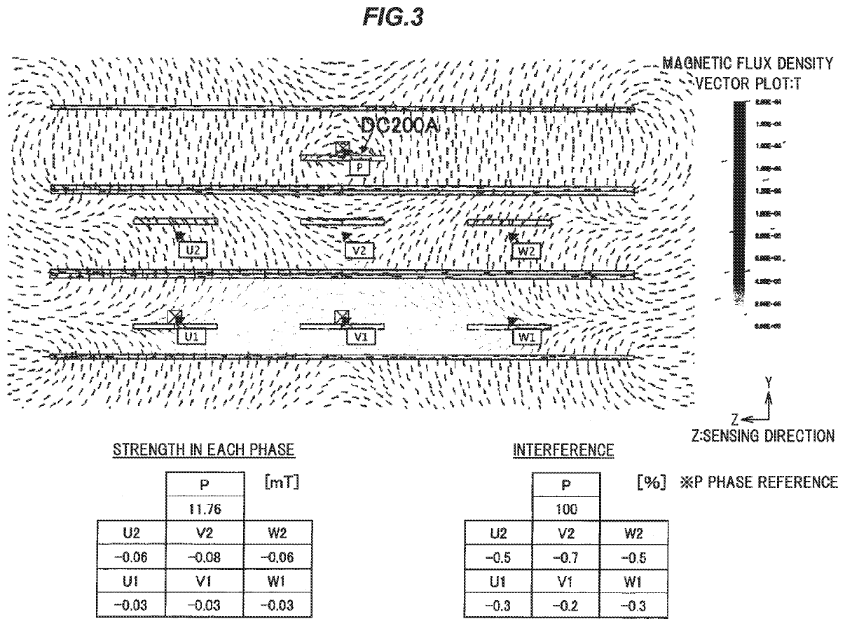

FIG. 3 is a diagram showing a computation result when a DC electric current was applied to the third bus bar 31 of the third electric current sensor module 30 in the electric current sensor 1 according to the first embodiment of the present invention. This was an analysis for observing an influence of the DC electric current flowing in the third bus bar 31 on the first electric current sensor module 10 and the second electric current sensor module 20. As a magnetic flux resulting from the DC electric current flowing in the third bus bar 31, when a magnetic flux density of 11.76 mT in the third magnetic detection element 33 was set at 100%, the strengths of the magnetic fluxes at the sensing positions of the first electric current sensor module 10 and the second electric current sensor module 20 were evaluated. As a result, the largest influence was a magnitude of 0.7% observed in the second V phase detection element 23b closest to the third bus bar 31. Accordingly, it was confirmed that the influence of the DC electric current flowing in the third bus bar 31 on the first electric current sensor module 10 and the second electric current sensor module 20 was able to be suppressed.

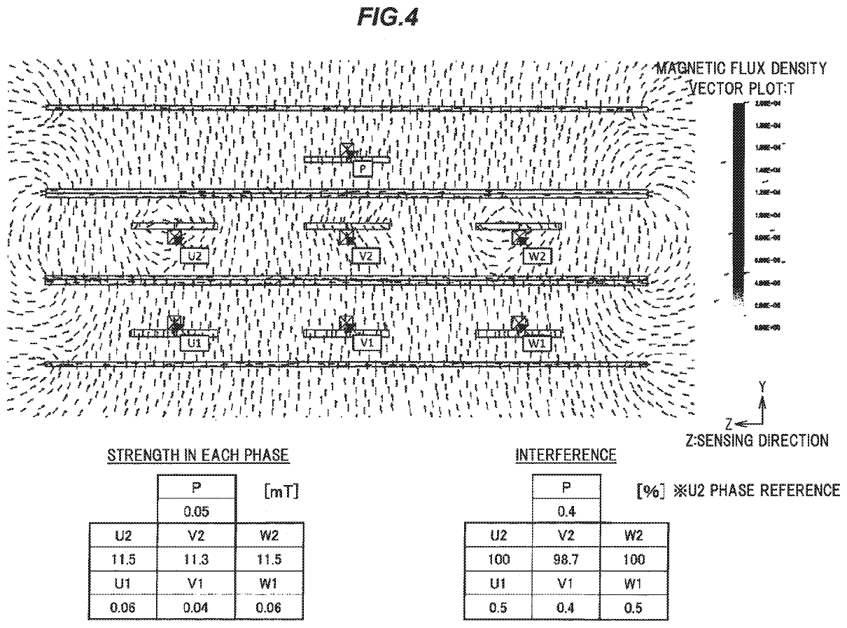

FIG. 4 is a diagram showing a computation result when a three-phase AC electric current was applied to the second bus bar 21 of the second electric current sensor module 20 in the electric current sensor 1 according to the first embodiment of the present invention. This was an analysis for observing an influence of the AC electric current flowing in the second bus bar 21 of the second electric current sensor module 20 on the first electric current sensor module 10 and the third electric current sensor module 30. When a magnetic flux density of 11.5 mT in the second U phase detection element 23a was set at 100%, the strengths of the magnetic fluxes at the sensing positions of the first electric current sensor module 10 and the third electric current sensor module 30 were evaluated. As a result, the largest influence was a magnitude of 0.5% observed in the first U phase detection element 13a and the first W phase detection element 13c. Accordingly, it was confirmed that the influence of the AC electric current flowing in the second bus bar 21 on the first electric current sensor module 10 and the third electric current sensor module 30 was able to be suppressed. Note that since the three-phase AC electric current was used, the magnetic flux density within the second shield plates 22 was smaller than the magnetic flux density within the third shield plates 32 observed when the DC electric current was applied to the third bus bar 31. Accordingly, the occurrence of a deterioration in the shield properties was suppressed.

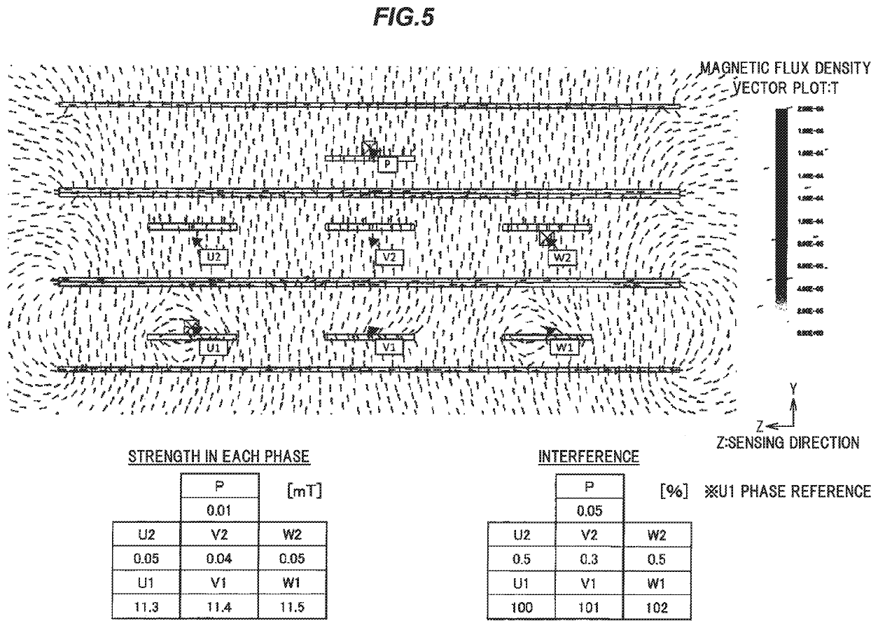

FIG. 5 is a diagram showing a computation result when a three-phase AC electric current was applied to the bus bar 11 of the first electric current sensor module 10 in the electric current sensor 1 according to the first embodiment of the present invention. This was an analysis for observing an influence of the AC electric current flowing in the first bus bar 11 of the first electric current sensor module 10 on the second electric current sensor module 20 and the third electric current sensor module 30. When a magnetic flux density of 11.3 mT in the first U phase detection element 13a was set at 100%, the strengths of the magnetic fluxes at the sensing positions of the second electric current sensor module 20 and the third electric current sensor module 30 were evaluated. As a result, the largest influence was a magnitude of 0.5% observed in the second U phase detection element 23a and the second W phase detection element 23c. Accordingly, it was confirmed that the influence of the AC electric current flowing in the first bus bar 11 on the second electric current sensor module 20 and the third electric current sensor module 30 was able to be suppressed. Note that since the three-phase AC electric current was used, the magnetic flux density within the first shield plates 12 was smaller than the magnetic flux density within the third shield plates 32 observed when the DC electric current was applied to the third bus bar 31. Accordingly, the occurrence of a deterioration in the shield properties was suppressed.

### Actions and Advantageous Effects of the Embodiment

(1) In order to suppress the influence of disturbance, the shields are required to exhibit its inherent properties. When the electric current flows in the bus bars and the magnetic flux density within the shields becomes high, there is a concern that a saturation of the magnetic bodies of the shields occurs, leading to a deterioration in the shield properties. In the present embodiment, since the first and the second electric current sensor modules 10 and 20 each have their three-phase bus bars, the sum of the electric currents becomes zero by sub-modularization per three phases. For this reason, an increase in the magnetic flux density within the shields is suppressed.

(2) The first electric current sensor module 10, the second electric current sensor module 20, and the third electric current sensor module 30 are arranged by superposition on top of each other in the height direction. At this point of time, the first upper shield plate 12a of the first electric current sensor module 10 and the second lower shield plate 22b of the second electric current sensor module 20 are arranged in such a manner as to be brought into contact with each other. Further, the second upper shield plate 22a of the second electric current sensor module 20 and the third lower shield plate 32b of the third electric current sensor module 30 are arranged in such a manner as to be brought into contact with each other. This makes it possible to configure the effectively thick shields between the electric current sensor modules 10 and 20 and between the electric current sensor modules 20 and 30, and therefore makes it possible to effectively suppress the occurrence of a saturation of the magnetic bodies.

(3) The first, the second, and the third magnetic detection elements 13, 23, and 33 included in the first, the second, and the third electric current sensor modules 10, 20, and 30 are arranged in the middle (halfway) in the height direction between the one pair of first shield plates 12, between the one pair of second shield plates 22, and between the one pair of third shield plates 32, respectively. Since, in the middle (halfway) in the height direction between each pair of the shield plates 12, 22, and 32, the directions of the magnetic flux densities resulting from the other phase electric currents flowing in the bus bars of the other electric current sensor modules are matched to the height direction, by matching the sensing directions of the first, the second, and the third magnetic detection elements 13, 23, and 33 to the width direction, it is possible to effectively suppress the interferences of the other phases.

(4) In the third electric current sensor module 30 to detect the single phase DC electric current, by making the sizes of the third shield plates 32 the same as the sizes of the first and the second shield plates 12 and 22 of the first and the second electric current sensor modules 10 and 20 to detect the three phase AC electric currents, it is possible to effectively suppress the interferences with the other phases.

(5) In the third electric current sensor module 30, by arranging the third bus bar 31 in the middle in the width direction, it is possible to resist being affected by the disturbance generating external magnetic field.

(6) In the first electric current sensor module 10 and the second electric current sensor module 20, since the first U phase bus bar 11a, the first V phase bus bar 11b, and the first W phase bus bar 11c are arranged at equally spaced intervals in the width direction, while the second U phase bus bar 21a, the second V phase bus bar 21b, and the second W phase bus bar 21c are arranged at equally spaced intervals in the width direction, it is possible to make the influences of the interferences of the other phases as even as possible.

### Second Embodiment

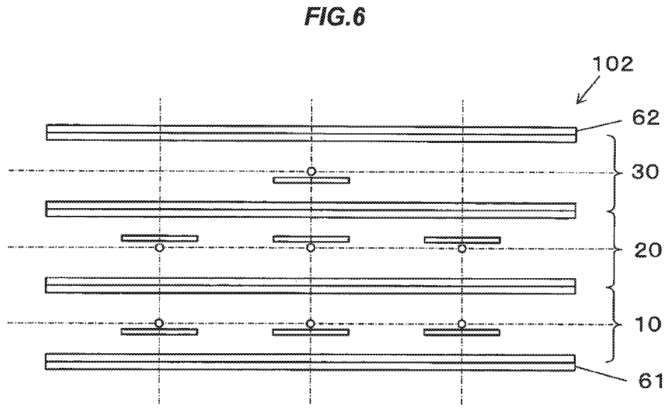

FIG. 6 is a cross-sectional view showing an electric current sensor 102 according to a second embodiment of the present invention. The same numerals are being assigned to the members common to those of the first embodiment. The electric current sensor 102 according to the second embodiment is different from the electric current sensor 1 of the first embodiment in that the electric current sensor 102 is being provided with an additional shield plate 61 beneath the first lower shield plate 12b, while being provided with an additional shield plate 62 over the third upper shield plate 32a. In other words, the shield plates 12b and 32a that are not in contact with the other electric current sensor module 22 are being provided with the additional shield plates 61 and 62, respectively.

Since the first electric current sensor module 10, the second electric current sensor module 20, and the third electric current sensor module 30 are arranged by superposition on top of each other in the height direction, the shields between the electric current sensor modules 10 and 20 and between the electric current sensor modules 20 and 30 are the effectively thick shield plates, but the first lower shield plate 12b and the third upper shield plate 32a, on which no shield plates respectively are being superposed, are relatively thin. In view of the foregoing, by providing the additional shield plates 61 and 62, the upper and lower shield plates become symmetrical in thickness, and it is therefore possible to efficiently suppress the influences of the interferences of the other phases on the shielding performance.

### Third Embodiment

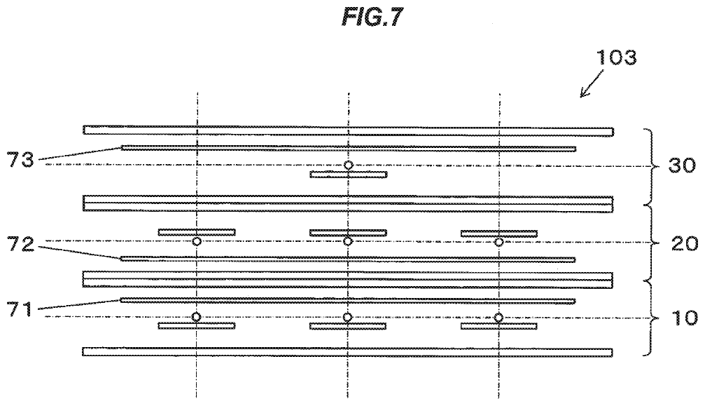

FIG. 7 is a cross-sectional view showing an electric current sensor 103 according to a third embodiment of the present invention. The electric current sensor 103 according to the third embodiment is different from the electric current sensor 1 according to the first embodiment in that, in the electric current sensor 103, the electric current sensor modules 10, 20, and 30 are each being provided with an electrical conducting body between their magnetic detection element and their one shield plate.

The first electric current sensor module 10 is being provided with a first electrical conducting plate 71 between the first upper shield plate 12a and the first magnetic detection element 13. The second electric current sensor module 20 is being provided with a second electrical conducting plate 72 between the second lower shield plate 22b and the second magnetic detection element 23. The third electric current sensor module 30 is being provided with a third electrical conducting plate 73 between the third upper shield plate 32a and the third magnetic detection element 33. The material for the first, the second, and the third electrical conducting bodies 71, 72, and 73 is made of a nonmagnetic electrical conducting material such as a copper or an aluminum or the like. The first electrical conducting body 71 is extending in the width direction in such a manner as to cover all the first U phase detection element 13a, the first V phase detection element 13b, and the first W phase detection element 13c. Similarly, the second electrical conducting body 72 is extending in the width direction in such a manner as to cover all the second U phase detection element 23a, the second V phase detection element 23b, and the second W phase detection element 23c. The first, the second, and the third electrical conducting bodies 71, 72, and 73 are preferably the same in size. By providing the first, the second, and the third electrical conducting bodies 71, 72, and 73, the response to the electric current can be improved.

### Fourth Embodiment

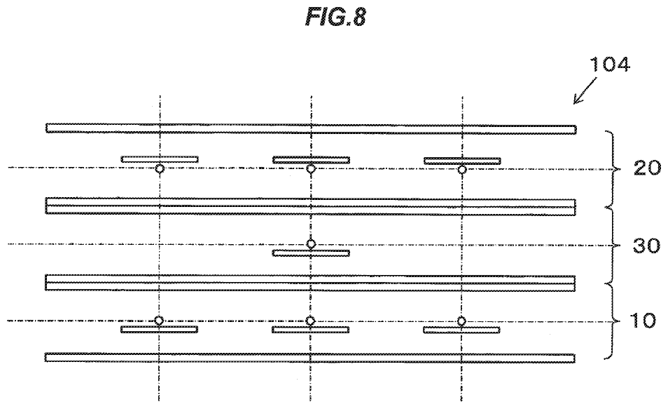

FIG. 8 is a cross-sectional view showing an electric current sensor 104 according to a fourth embodiment of the present invention. The electric current sensor 104 according to the fourth embodiment is different in the superposing order of the first, the second, and the third electric current sensor modules 10, 20, and 30 from the electric current sensor 1 according to the first embodiment. That is, the electric current sensor modules 10, 20, and 30 are arranged in such a manner that the first electric current sensor module 10 and the second electric current sensor module 20, which are designed to be compatible with the three-phase AC electric current, sandwich the third electric current sensor module 30 therebetween, which is designed to be compatible with the single-phase DC electric current. By arranging the electric current sensor modules 10, 20, and 30 in this way, the electric current sensor 104 becomes symmetrical in vertical direction (in the height direction), and it is therefore possible to effectively suppress the interferences of the other phases.

Although the embodiments of the present invention have been described above, the above described embodiments are not to be construed as limiting the inventions according to the claims. Further, it should be noted that not all the combinations of the features described in the embodiments are indispensable to the means for solving the problem of the invention. The present invention can appropriately be modified and implemented without departing from the spirit of the present invention.

Although, in the above embodiments, the electric current sensor is configured to include the two three-phase AC electric current sensor modules and the one single-phase DC electric current sensor module, the electric current sensor may be configured to include three three-phase AC electric current sensor modules, for example. In addition, although the electric current sensor is configured to include the three electric current sensor modules, at least one electric current sensor module may be added thereto in such a manner that four or more in total of the electric current sensor modules may be arranged by superposition on top of each other.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An electric current sensor, comprising:
first, second, and third electric current sensor modules, each including at least one bus bar formed in a rectangular shape extending in a width direction in cross section, to carry an electric current along a length direction perpendicular to the width direction, one pair of shield plates made of a magnetic material and disposed in a height direction perpendicular to the width direction and the length direction in such a manner as to sandwich the at least one bus bar therebetween, and at least one magnetic detection element disposed between the at least one bus bar and one of the one pair of shield plates, to detect a strength of a magnetic field in the width direction,
wherein the first, the second, and the third electric current sensor modules are arranged by superposition on top of each other in the height direction.

2. The electric current sensor according to claim 1, wherein the first and the second electric current sensor modules each include three bus bars and three magnetic detection elements.

3. The electric current sensor according to claim 2, wherein the third electric current sensor module includes one bus bar and one magnetic detection element.

4. The electric current sensor according to claim 2, wherein the three magnetic detection elements included in the first electric current sensor module and the three magnetic detection elements included in the second electric current sensor module are arranged in the same locations in the width direction.

5. The electric current sensor according to claim 4, wherein the one magnetic detection element included in the third electric current sensor module is arranged in the same location in the width direction as the magnetic detection elements located in a middle in the width direction, of the three magnetic detection elements included in the first electric current sensor module and the three magnetic detection elements included in the second electric current sensor module.

6. The electric current sensor according to claim 1, wherein the magnetic detection elements included in the first, the second, and the third electric current sensor modules are arranged halfway in the height direction between the one pair of shield plates of the first, the second, and the third electric current sensor modules, respectively.

7. The electric current sensor according to claim 1, wherein the one pairs of shield plates included in the first, the second, and the third electric current sensor modules are the same in size.

8. The electric current sensor according to claim 1, wherein at least one of the first, the second, and the third electric current sensor modules is being provided with an electrical conducting body made of a nonmagnetic electrical conducting material tween the at least one magnetic detection element thereof and one of the one pair of shield plates thereof.

9. The electric current sensor according to claim 1, further comprising:
additional shield plates, which, with the first, the second, and the third electric current sensor modules being arranged by superposition on top of each other in the height direction, are being provided on a lower side of a lowermost shield plate and an upper side of an uppermost shield plate, respectively, located in the first, the second, and the third electric current sensor modules.

10. The electric current sensor according to claim 1, further comprising:
at least one electric current sensor module, which is arranged by superposition on top of the first, the second, and the third electric current sensor modules, in addition to the first, the second, and the third electric current sensor modules.
